(19) United States
(12) Patent Application Publication
(10) Pub. No.: US 2023/0245886 A1
(43) Pub. Date: Aug. 3, 2023

(54) IMAGING DEVICE, SEMICONDUCTOR FILM, AND DISPERSION LIQUID

(71) Applicant: SONY GROUP CORPORATION, TOKYO (JP)

(72) Inventors: SYUUITI TAKIZAWA, TOKYO (JP); MICHINORI SHIOMI, TOKYO (JP); YOSUKE SAITO, TOKYO (JP); MAMORU TANABE, TOKYO (JP); SHUNSUKE YAMASHITA, TOKYO (JP)

(21) Appl. No.: 18/004,278

(22) PCT Filed: Jun. 14, 2021
(86) PCT No.: PCT/JP2021/022448

§ 371 Date: Jan. 4, 2023

(30) Foreign Application Priority Data
Jul. 17, 2020 (JP) 2020-123305

(51) Int. Cl. H01L 21/02; H01L 27/146

(52) U.S. Cl. CPC H01L 21/02601; H01L 27/146; B82Y 30/00

(57) ABSTRACT

An imaging device including a photoelectric conversion layer including a semiconductor nanoparticle (100) including a particle body (101) and a monoatomic ligand (102). The particle body (101) includes a semiconductor core (103) including at least two or more elements selected from a Group I element, a Group III element, a Group V element, and a Group VI element. The monoatomic ligand (102) is bonded to a surface of the particle body (101).

### TECHNICAL FIELD

The present disclosure relates an imaging device, a semiconductor film, and a dispersion liquid.

### BACKGROUND ART

In recent years, photoelectric conversion elements have been proposed that include semiconductor nanoparticles in photoelectric conversion layers, which is referred to as quantum dots (e.g., PTL 1).

### CITATION LIST

### Patent Literature

PTL 1: Japanese Unexamined Patent Application Publication No. 2014-112623

### SUMMARY OF THE INVENTION

An imaging device including such a photoelectric conversion element is requested to exhibit higher response characteristics in photoelectric conversion. It is therefore desired to further increase the mobility of electric charge in a photoelectric conversion layer by decreasing the distance between semiconductor nanoparticles included in the photoelectric conversion layer.

It is desirable to provide an imaging device in which the mobility of electric charge in a photoelectric conversion layer is increased, a semiconductor film included in the photoelectric conversion layer, and a dispersion liquid that allows the semiconductor film to be formed.

An imaging device according to an embodiment of the present disclosure includes a photoelectric conversion layer including a semiconductor nanoparticle including a particle body and a monoatomic ligand. The particle body includes a semiconductor core. The monoatomic ligand is bonded to a surface of the particle body.

A semiconductor film according to an embodiment of the present disclosure includes a semiconductor nanoparticle including a particle body and a monoatomic ligand. The particle body includes a semiconductor core including at least two or more elements selected from a Group I element, a Group III element, a Group V element, and a Group VI element. The monoatomic ligand is bonded to a surface of the particle body.

A dispersion liquid according to an embodiment of the present disclosure includes a semiconductor nanoparticle including a particle body and a monoatomic ligand. The particle body includes a semiconductor core including at least two or more elements selected from a Group I element, a Group III element, a Group V element, and a Group VI element. The monoatomic ligand is bonded to a surface of the particle body.

The imaging device, the semiconductor film, and the dispersion liquid according to the respective embodiments of the present disclosure each include the semiconductor nanoparticle including the particle body and the monoatomic ligand as a photoelectric conversion material. The particle body includes the semiconductor core. The monoatomic ligand is bonded to the surface of the particle body. This makes it possible to further decrease, for example, the inter-particle distance between the semiconductor nanoparticles.

### BRIEF DESCRIPTION OF DRAWING

FIG. 1 is a schematic cross-sectional view of a configuration of a semiconductor nanoparticle according to an embodiment of the present disclosure.

FIG. 2 is an explanatory diagram illustrating that a TEM observation result of a particle body of the semiconductor nanoparticle and an EDX analysis result of a monoatomic ligand coordinated to a surface of the particle body are overlaid.

FIG. 3 is a graphical chart illustrating a UV-Vis-NIR spectrum of the semiconductor nanoparticle.

FIG. 4 is a schematic cross-sectional view of a configuration of a semiconductor nanoparticle according to a modification example of the embodiment.

FIG. 5 is a schematic diagram illustrating a configuration of a dispersion liquid according to another embodiment of the present disclosure.

FIG. 6 is a schematic diagram illustrating a configuration of a semiconductor film according to still another embodiment of the present disclosure.

FIG. 7 is a schematic diagram illustrating a configuration of a semiconductor film according to a modification example of the embodiment.

FIG. 8 is a schematic diagram describing an outline of an overall configuration of an imaging device according to an embodiment of the present disclosure.

FIG. 9 is a vertical cross-sectional view of an example of a cross-sectional configuration of a pixel in the imaging device according to the embodiment.

FIG. 10 is a vertical cross-sectional view of another example of the cross-sectional configuration of the pixel in the imaging device according to the embodiment.

FIG. 11 is a block diagram illustrating a configuration example of an electronic apparatus including an imaging device according to an embodiment of the present disclosure.

FIG. 12 is a view depicting an example of a schematic configuration of an endoscopic surgery system.

FIG. 13 is a block diagram depicting an example of a functional configuration of a camera head and a camera control unit (CCU).

FIG. 14 is a block diagram depicting an example of schematic configuration of a vehicle control system.

FIG. 15 is a diagram of assistance in explaining an example of installation positions of an outside-vehicle information detecting section and an imaging section.

### MODES FOR CARRYING OUT THE INVENTION

The following describes an embodiment of the present disclosure in detail with reference to the drawings. The embodiment described below is a specific example of the present disclosure. The technology according to the present disclosure is not limited to the following modes. In addition, the disposition, dimensions, dimensional ratios, and the like of the respective components according to the present disclosure are not limited to the modes illustrated in the drawings.

It is to be noted that description is given in the following order.

### 1. Semiconductor Nanoparticle

### 1.1. Configuration Example

### 1.2. Experimental Example

### 1.3. Modification Example

### 2. Dispersion Liquid

### 3. Semiconductor Film

### 4. Imaging Device

### 4.1. Overall Configuration

### 4.2. Pixel Configuration

### 5. Application Examples

### <1. Semiconductor Nanoparticle>

### 1.1. Configuration Example

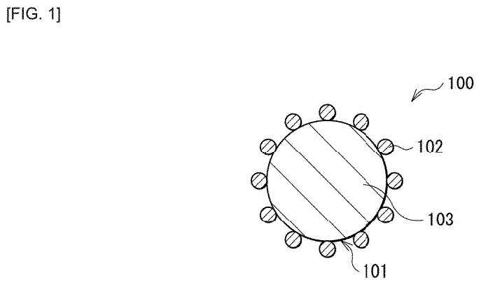

First, a semiconductor nanoparticle according to an embodiment of the present disclosure is described with reference to FIG. 1. FIG. 1 is a schematic cross-sectional view of a configuration of a semiconductor nanoparticle 100 according to the present embodiment.

The semiconductor nanoparticle 100 is a semiconductor crystal having a particle size of several nm to several tens of nm. It is possible to control the width of the band gap of the semiconductor nanoparticle 100 by using the composition and the particle size thereof. In addition, it is possible to increase the quantum efficiency of the semiconductor nanoparticle 100 by using a multi-exciton generation effect. This attracts attention as a photoelectric conversion material.

In a case where the semiconductor nanoparticle 100 according to the present embodiment is used as a photoelectric conversion material, it is possible to photoelectrically convert light in a wider wavelength band. For example, in a case where the semiconductor nanoparticle 100 according to the present embodiment has a narrower band gap, it is possible to increase the absorption edge wavelength of the semiconductor nanoparticle 100. This allows an imaging device including the semiconductor nanoparticle 100 according to the present embodiment in a photoelectric conversion layer to detect, for example, near-infrared rays (Near-InfraRed: NIR).

As illustrated in FIG. 1, the semiconductor nanoparticle 100 according to the present embodiment includes a particle body 101 and a monoatomic ligand 102.

The particle body 101 includes a semiconductor core 103 including a compound semiconductor including at least two or more elements selected from a Group I element, a Group III element, a Group V element, and a Group VI element. The semiconductor core 103 includes a compound semiconductor. This allows the semiconductor core 103 to absorb light and generate an exciton (exciton). This allows the photoelectric conversion layer including the semiconductor nanoparticle 100 to separate an electron and a hole by using the generated exciton and it is thus possible to convert light energy into electric energy.

For example, the semiconductor core 103 of the particle body 101 may include a compound semiconductor including at least one or more of InN, InAs, InSb, Ag₂S, Ag₂Se, Ag₂Te, CuFeS₂, CuFeSe₂, or AgSbSe₂. In a case where the semiconductor core 103 includes a compound semiconductor that does not include Pb (lead), which is a Group IV element, this allows the semiconductor core 103 to further increase the safety of the semiconductor nanoparticle 100. In addition, in a case where the semiconductor core 103 includes a compound semiconductor that does not include Zn (zinc), which is a Group II element, this allows the semiconductor core 103 to have a narrower band gap. It is thus possible to absorb light having a longer wavelength such as near-infrared rays.

Specifically, the semiconductor core 103 of the particle body 101 may include a compound semiconductor including each of a Group I element and a Group VI element. For example, the semiconductor core 103 may include a compound semiconductor including at least one or more of AgInSe₂, AgInTe₂, Ag₂Se, or Ag₂Te. This allows the semiconductor nanoparticle 100 to absorb light in a wider wavelength band.

For example, Table 1 below illustrates the absorption edge wavelengths of AgInSe₂, AgInTe₂, Ag₂Se, and Ag₂Te in the bulk state. It is to be noted that Table 1 also illustrates even the absorption edge wavelength of CuInS₂ in the bulk state for comparison.

TABLE 1

| compound | absorption edge wavelength in bulk state |
|---|---|
| AgInSe₂ | 1008 nm |
| AgInTe₂ | 1292 nm |
| Ag₂Se | 8267 nm |
| Ag₂Te | 1851 nm |
| CuInS₂ | 810 nm |

As illustrated in Table 1, the absorption edge wavelengths of AgInSe₂, AgInTe₂, Ag₂Se, and Ag₂Te in the bulk state each shift to the long wavelength side. It is thus considered that the semiconductor nanoparticle 100 is able to absorb light in a wider wavelength band in a case where the semiconductor core 103 of the particle body 101 includes AgInSe₂, AgInTe₂, Ag₂Se, or Ag₂Te. In particular, Ag₂Se has an absorption edge wavelength of more than 1400 nm in the bulk state. It is therefore considered that the semiconductor nanoparticle 100 including the semiconductor core 103 including Ag₂Se is able to absorb light in a wide wavelength band from ultraviolet rays to near-infrared rays. It is thus considered that an imaging device including the semiconductor nanoparticle 100 like this in a photoelectric conversion layer is able to detect light in a wider wavelength range.

The monoatomic ligand 102 is a ligand including one atom and bonded to the surface of the particle body 101. Specifically, the monoatomic ligand 102 may be any of a chlorine atom, a bromine atom, an iodine atom, or a sulfur atom. More specifically, the monoatomic ligand 102 may be a sulfur atom ionized into a divalent ion (i.e., a sulfide ion). The plurality of monoatomic ligands 102 bonded to the surface of each of the particle bodies 101 allows the semiconductor nanoparticles 100 to be dispersed more. This makes it possible to suppress the aggregation of the semiconductor nanoparticles 100.

Ligands such as the monoatomic ligands 102 bonded to the surface of the particle body 101 are provided to control the characteristics of the semiconductor nanoparticle 100 such as solubility, reactivity, or stability in a case where the semiconductor nanoparticle 100 is formed by using a solution method or the like. As ligands bonded to the surfaces of the particle bodies 101 have longer chains, the ligands have higher stability and allow the semiconductor nanoparticles 100 to be dispersed more. Meanwhile, the ligands, however, increase the inter-particle distance between the semiconductor nanoparticles 100 and thus decrease the inter-particle mobility of electric charge.

The technology according to the present disclosure adopts the monoatomic ligands 102 each including one atom as ligands bonded to the surfaces of the particle bodies 101 of the semiconductor nanoparticles 100 to make it possible to decrease the inter-particle distance between the semiconductor nanoparticles 100 and further increase the inter-particle mobility of electric charge.

For example, Table 2 below illustrates the types and the molecular chain lengths of ligands bonded to the surface of the particle body 101. It is to be noted that oleylamine, oleic acid, and 1-dodecanethiol in Table 2 are ligands typically used to form the semiconductor nanoparticle 100 by using a solution method or the like.

TABLE 2

| ligand | molecular chain length |
|---|---|
| oleylamine | 2.225 nm |
| oleic acid | 2.228 nm |
| 1-dodecanethiol | 1.516 nm |
| 3-mercaptopropionic acid | 0.520 nm |
| thiocyanate | 0.295 nm |
| benzenethiol | 0.461 nm |
| sulfur atom | 0.2 nm |

As illustrated in Table 2, a sulfur atom has an extremely shorter molecular chain length than the molecular chain lengths of the other ligands. Sulfur atoms bonded to the particle bodies 101 as the monoatomic ligands 102 thus make it possible to further decrease the inter-particle distance between the semiconductor nanoparticles 100. The monoatomic ligands 102 thus make it possible to further increase the inter-particle mobility of electric charge between the semiconductor nanoparticles 100.

The semiconductor nanoparticles 100 like these may be formed by substituting the ligands bonded to the surfaces of the semiconductor nanoparticles 100 with the monoatomic ligands 102 after formation by using, for example, a solution method or the like. It is possible to substitute the ligands on the semiconductor nanoparticles 100, for example, in the following method.

Specifically, first, the semiconductor nanoparticles 100 are prepared that are formed in a solution method and have long chain molecules such as oleic acid coordinated to the surfaces of the particle bodies 101. Next, the semiconductor nanoparticles 100 to which the long chain molecules are coordinated are dispersed in a less polar solvent such as octane and a substrate or the like is then coated with the dispersion liquid of the semiconductor nanoparticles 100 in a spin coating method. After that, a solution in which compounds (e.g., chlorides, bromides, iodides, or sulfides of tetrabutylammonium) including chlorine atoms, bromine atoms, iodine atoms, or sulfur atoms as ions are dissolved in a polar solvent is dropped on the semiconductor nanoparticles 100 with which the substrate or the like is coated. After that, a polar solvent is dropped on the semiconductor nanoparticles 100 to wash away the substituted ligands of the long chain molecules. The dropping and washing operations described above are repeated about ten times. This makes it possible to substitute the ligands such as oleic acid with chlorine atoms, bromine atoms, iodine atoms, or sulfur atoms.

The semiconductor nanoparticles 100 according to the present embodiment are each able to absorb light in a wide wavelength band including near-infrared rays. In addition, the semiconductor nanoparticles 100 according to the present embodiment make it possible to increase the inter-particle mobility of electric charge. This allows an imaging device including a photoelectric conversion layer including the semiconductor nanoparticles 100 according to the present embodiment to exhibit higher response characteristics in photoelectrically converting light in a wide wavelength band including near-infrared rays.

### 1.2. Experimental Example

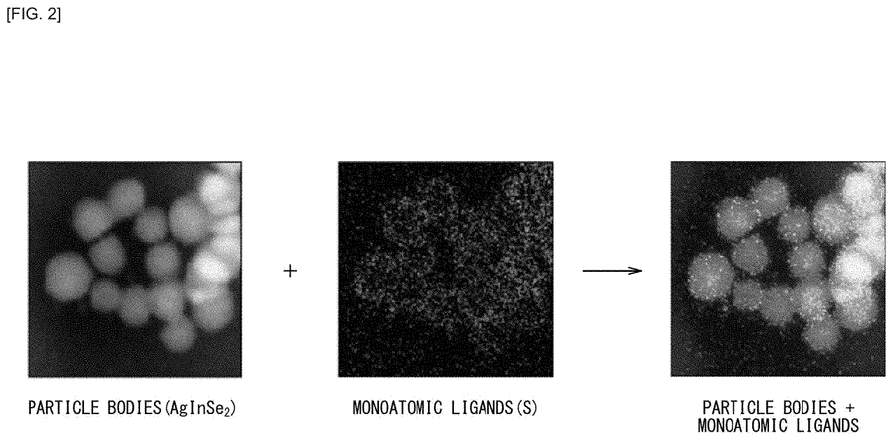

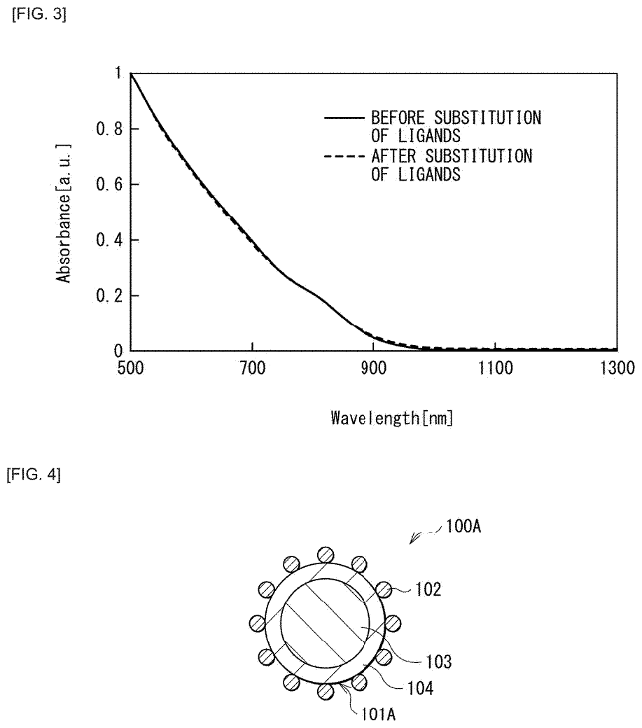

Next, an experimental example of the semiconductor nanoparticle according to the present embodiment is described with reference to FIGS. 2 and 3.

It is possible to form a semiconductor nanoparticle by using a solution method. Specifically, silver acetate, indium acetate, and selenourea were added to oleylamine and this was reacted at 250° C. for ten minutes under an N₂ atmosphere to form a semiconductor nanoparticle including a semiconductor core including AgInSe₂. In addition, oleylamine used as a solution was present as a ligand on the surface of the formed semiconductor nanoparticle. It is to be noted that the semiconductor nanoparticles had, for example, an average particle size (e.g., the average diameter of the semiconductor nanoparticles in a case where the semiconductor nanoparticles each have a shape that resembles a sphere) of 3 nm or more and 10 nm or less.

After that, the long chain molecules of the ligands coordinated to the surfaces of the particle bodies were substituted with sulfur atoms serving as monoatomic ligands by adding an ammonium sulfide aqueous solution to the solution including the semiconductor nanoparticles formed above. Subsequently, the long chain molecules were washed away and removed by exchanging the solvent of the solution including the semiconductor nanoparticles.

FIG. 2 illustrates a TEM (Transmission Electron Microscope) observation result of the particle bodies of the semiconductor nanoparticles formed above, an EDX (Energy Dispersive X-ray spectroscopy) analysis result of the monoatomic ligands coordinated to the surfaces of the particle bodies, and an image in which these results are overlaid.

As illustrated in FIG. 2, sulfur atoms serving as monoatomic ligands are distributed on the surfaces of the particle bodies of semiconductor nanoparticles and the ligands on the surfaces of the particle bodies are appropriately substituted with the monoatomic ligands in the method described above. This indicates that the semiconductor nanoparticles according to the present embodiment are formed.

In addition, FIG. 3 illustrates the UV-Vis-NIR spectrum of a semiconductor nanoparticle formed above. FIG. 3 illustrates both the UV-Vis-NIR spectrum of a semiconductor nanoparticle whose ligands have not yet been substituted in an ammonium sulfide aqueous solution (i.e., the ligands are long chain molecules) and the UV-Vis-NIR spectrum of the semiconductor nanoparticle whose ligands have been substituted (i.e., the ligands are monoatomic ligands).

As illustrated in FIG. 3, the UV-Vis-NIR spectrum of the semiconductor nanoparticle according to the present embodiment does not change in shape before and after the ligands are substituted. This indicates that the substitution of the ligands in an ammonium sulfide aqueous solution has no influence on the optical characteristics.

In addition, a semiconductor nanoparticle whose semiconductor core includes AgInSe₂ has an absorption edge wavelength of about 1000 nm and this indicates that the absorption edge wavelength of the semiconductor nanoparticle is substantially the same as the absorption edge wavelength in the bulk state. This indicates that, in a case where the semiconductor core includes a compound semiconductor having a longer absorption edge wavelength in the bulk state as described above, the semiconductor nanoparticle is able to absorb light in a wide wavelength band from ultraviolet rays to near-infrared rays.

### 1.3. Modification Example

Subsequently, a modification example of the semiconductor nanoparticle 100 illustrated in FIG. 1 is described with reference to FIG. 4. FIG. 4 is a schematic cross-sectional view of a configuration of a semiconductor nanoparticle 100A according to the modification example.

As illustrated in FIG. 4, the particle body 101A of the semiconductor nanoparticle 100A may include the semiconductor core 103 and a shell 104. In other words, the particle body 101A of the semiconductor nanoparticle 100A may be provided to have a core-shell structure in which the shell 104 is formed to cover the semiconductor core 103. It is to be noted that the monoatomic ligand 102 is similar to that of the semiconductor nanoparticle 100 illustrated in FIG. 1 and description thereof is thus omitted here.

As in the semiconductor nanoparticle 100 illustrated in FIG. 1, the semiconductor core 103 includes a compound semiconductor including at least two or more elements selected from a Group I element, a Group III element, a Group V element, and a Group VI element. Specifically, the semiconductor core 103 may include a compound semiconductor including at least one or more of InN, InAs, InSb, Ag₂S, Ag₂Se, Ag₂Te, CuFeS₂, CuFeSe₂, or AgSbSe₂. More specifically, the semiconductor core 103 may include a compound semiconductor including each of a Group I element and a Group VI element. For example, the semiconductor core 103 may include a compound semiconductor including at least one or more of AgInSe₂, AgInTe₂, Ag₂Se, or Ag₂Te.

The shell 104 is provided to cover the semiconductor core 103 with a compound semiconductor. The shell 104 is able to further stabilize the semiconductor nanoparticle 100A by protecting the semiconductor core 103. Specifically, the shell 104 may be provided to include at least one or more of PbO, PbO₂, Pb₃O₄, ZnS, ZnSe, ZnTe, GaS, or GaSe. It is to be noted that the shell 104 is preferably provided by using a compound semiconductor having a shorter absorption edge wavelength than the wavelength band of light to be absorbed by the semiconductor nanoparticle 100A to avoid preventing the semiconductor core 103 from absorbing light.

### <2. Dispersion Liquid>

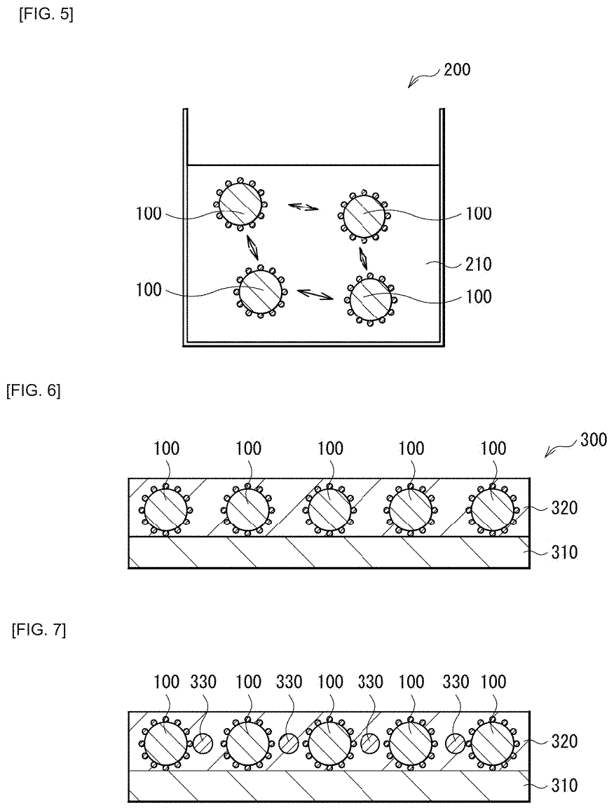

Next, a dispersion liquid according to another embodiment of the present disclosure is described with reference to FIG. 5. FIG. 5 is a schematic diagram illustrating a configuration of a dispersion liquid 200 according to the present embodiment. The dispersion liquid 200 is, for example, an ink used to form a semiconductor film including the semiconductor nanoparticles 100.

As illustrated in FIG. 5, the dispersion liquid 200 according to the present embodiment is configured by dispersing the semiconductor nanoparticles 100 described above in a dispersion solvent 210. The dispersion liquid 200 allows the semiconductor nanoparticles 100 to be dispersed without being aggregated because the electrostatic repulsion of the ionized monoatomic ligands 102 allows the semiconductor nanoparticles 100 to repel each other. The dispersion solvent 210 may be, for example, a very polar solvent. In such a case, the dispersion solvent 210 allows the semiconductor nanoparticles 100 including the ionized monoatomic ligands 102 to be dispersed more appropriately.

The dispersion liquid 200 according to the present embodiment disperses the semiconductor nanoparticles 100 including the monoatomic ligands 102 in the dispersion solvent 210 in advance to make it possible to avoid substituting ligands after a film of the semiconductor nanoparticles 100 is formed by coating. This allows the dispersion liquid 200 according to the present embodiment to prevent the film including the semiconductor nanoparticles 100 from having a crack or the like in a case where the ligands of the semiconductor nanoparticles 100 formed by coating are substituted.

### <3. Semiconductor Film>

Subsequently, a semiconductor film according to still another embodiment of the present disclosure is described with reference to FIG. 6. FIG. 6 is a schematic diagram illustrating a configuration of a semiconductor film 300 according to the present embodiment. The semiconductor film 300 may be used, for example, as a photoelectric conversion layer of an imaging device.

As illustrated in FIG. 6, the semiconductor film 300 according to the present embodiment may be configured by dispersing the semiconductor nanoparticles 100 described above in a film formation material 320 on a substrate 310 or the like. The film formation material 320 may be, for example, an electrically conductive polymer or the like. Alternatively, the film formation material 320 may be a semiconductor material having a different electrical conduction type from that of the semiconductor nanoparticle 100. Further, the semiconductor film 300 may include the semiconductor nanoparticles 100 alone that are formed on the substrate 310 by coating in place of the film formation material 320.

It is possible to form the semiconductor film 300 by forming a film of the dispersion liquid 200 on the substrate 310 by coating in a spin coating method or the like and removing the dispersion solvent 210 of the dispersion liquid 200. In the dispersion liquid 200, for example, the semiconductor nanoparticles 100 are dispersed.

In addition, a modification example of the semiconductor film 300 is described with reference to FIG. 7. FIG. 7 is a schematic diagram illustrating a configuration of a semiconductor film 300A according to a modification example of the present embodiment.

As illustrated in FIG. 7, the semiconductor film 300A may further include a metal ion 330 in an inter-particle space between the semiconductor nanoparticles 100.

Specifically, the metal ion 330 is a cation. For example, the metal ion 330 may be any of an alkali metal ion, an alkaline earth metal ion, or a transition metal ion. The metal ion 330 allows the dispersion solvent 210 to be removed by ion exchange. This makes it possible to further decrease the inter-particle distance between the semiconductor nanoparticles 100. The dispersion solvent 210 is trapped in an inter-particle space between the semiconductor nanoparticles 100 by electrostatic attraction force. In addition, the metal ion 330 allows electrostatic attraction force to be generated between the metal ion 330 and the ionized monoatomic ligand 102. This also makes it possible to further decrease the inter-particle distance between the semiconductor nanoparticles 100.

### <4. Imaging Device>

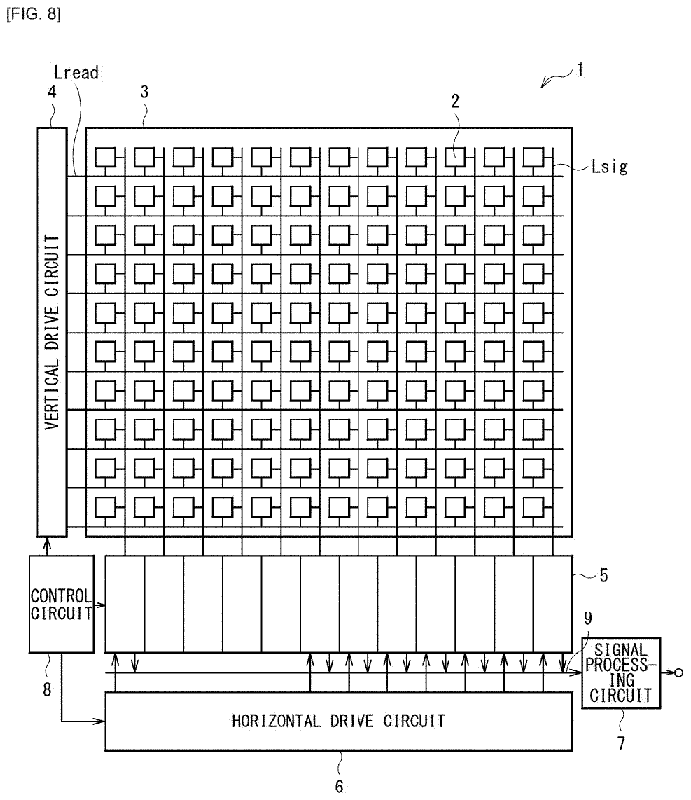

Next, an imaging device according to an embodiment of the present disclosure is described with reference to FIGS. 8 to 10. The imaging device according to the present embodiment is an imaging device that includes a photoelectric conversion layer including the semiconductor nanoparticle 100 and acquires a pixel signal on the basis of electric charge resulting from photoelectric conversion by the photoelectric conversion layer including the semiconductor nanoparticle 100.

### 4.1. Overall Configuration

First, an overall configuration of the imaging device according to the present embodiment is described with reference to FIG. 8. FIG. 8 is a schematic diagram describing an outline of an overall configuration of an imaging device 1 according to an embodiment of the present disclosure.

As illustrated in FIG. 8, the imaging device 1 according to the present embodiment includes, for example, a pixel array unit 3 and a peripheral circuit portion. The pixel array unit 3 includes pixels 2 that are two-dimensionally arranged in a matrix. The peripheral circuit portion includes a vertical drive circuit 4, a column signal processing circuit 5, a horizontal drive circuit 6, a signal processing circuit 7, and a control circuit 8. The pixel array unit 3 and the peripheral circuit portion may be provided on a substrate including a semiconductor such as silicon (Si).

Each of the pixels 2 includes a photoelectric conversion layer and a pixel transistor group. The photoelectric conversion layer includes the semiconductor nanoparticle 100 described above. The pixel transistor group converts optical charge generated by the photoelectric conversion layer into a pixel signal. The pixel transistor group includes, for example, a plurality of MOS (Metal-Oxide-Semiconductor) transistors including an amplifier transistor, a reset transistor, a selection transistor, and the like.

The control circuit 8 generates a variety of signals for causing the respective circuits included in the peripheral circuit portion to operate and outputs the variety of generated signals to the respective circuits. Specifically, the control circuit 8 generates clock signals and control signals on the basis of a vertical synchronization signal, a horizontal synchronization signal, and a master clock. The clock signals and the control signals are for controlling operations of the vertical drive circuit 4, the column signal processing circuit 5, the horizontal drive circuit 6, and the like. In addition, the control circuit 8 outputs the generated clock signals and control signals to the vertical drive circuit 4, the column signal processing circuit 5, and the horizontal drive circuit 6.

The vertical drive circuit 4 includes, for example, a shift register. The vertical drive circuit 4 selects a predetermined pixel drive line Lread and supplies the selected pixel drive line Lread with pulse signals for driving the pixels 2. This allows the vertical drive circuit 4 to drive the pixels 2 row by row. In other words, the vertical drive circuit 4 sequentially selects the respective pixels 2 of the pixel array unit 3 row by row while scanning the pixels 2 of the pixel array unit 3 in the vertical direction. The vertical drive circuit 4 causes a pixel signal based on optical charge generated by the photoelectric conversion section of each of the pixels 2 to be outputted to the signal processing circuit 7 through a vertical signal line Lsig.

The column signal processing circuit 5 is provided for each column of the pixels 2. The column signal processing circuit 5 performs signal processing on the pixel signals outputted from the pixels 2 for each column of the pixels 2. For example, the column signal processing circuit 5 may perform signal processing including a CDS (Correlated Double Sampling: correlated double sampling) process, an AD (Analog-Digital) conversion process, and the like on the pixel signals outputted from the pixels 2. The CDS process is a process for removing fixed pattern noise specific to the pixels 2.

The horizontal drive circuit 6 includes, for example, a shift register. The horizontal drive circuit 6 sequentially selects the respective column signal processing circuits 5 by using horizontal scanning pulse signals and causes the respective column signal processing circuits 5 to output pixel signals to a horizontal signal line 9.

The signal processing circuit 7 performs predetermined signal processing on the pixel signals sequentially outputted from the respective column signal processing circuits 5 through the horizontal signal line 9 and outputs the pixel signals subjected to the signal processing to the outside of the imaging device 1. For example, the signal processing circuit 7 may perform, on the pixel signals, predetermined signal processing such as dark current correction, column variation correction, or various kinds of digital signal processing. Alternatively, the signal processing circuit 7 may only buffer the pixel signals.

The imaging device 1 having the configuration described above is a CMOS image sensor of a so-called column AD type in which the column signal processing circuit 5 is provided for each column of the pixels 2. The imaging device 1 may also be, however, a CMOS image sensor of a pixel AD type in which the column signal processing circuit 5 is provided for each of the pixels 2.

### 4.2. Pixel Configuration

### First Configuration Example

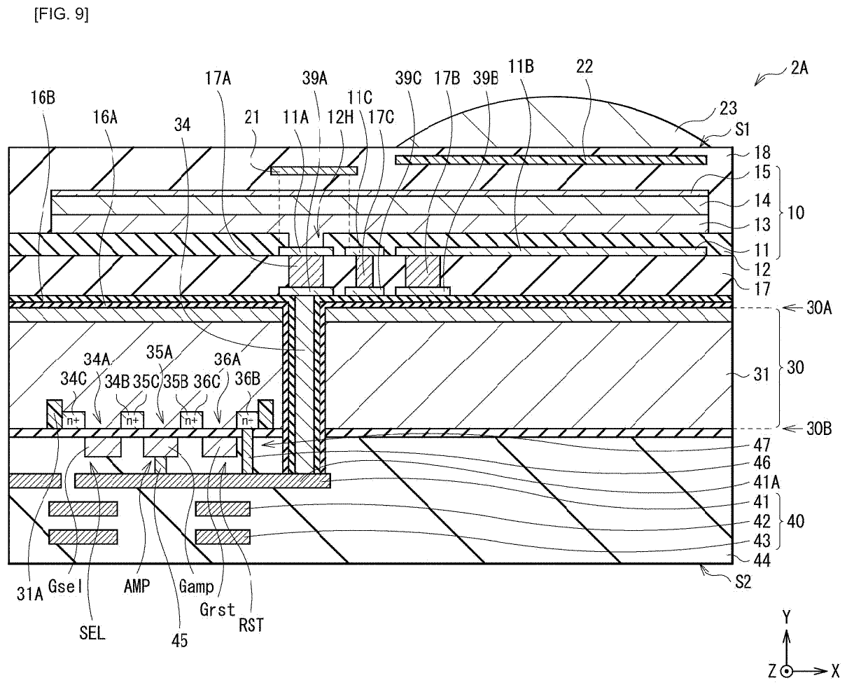

Subsequently, a first configuration example of the pixel 2 in the imaging device 1 according to the present embodiment is described more specifically with reference to FIG. 9. FIG. 9 is a vertical cross-sectional view of a cross-sectional configuration of a pixel 2A according to the first configuration example.

As illustrated in FIG. 9, the pixel 2A is provided, for example, with a photoelectric conversion section 10 on a first surface (also referred to as back surface) 30A side of a semiconductor substrate 30. The photoelectric conversion section 10 includes a photoelectric conversion layer 14 between a lower electrode 11 and an upper electrode 15 disposed to be opposed to each other. The photoelectric conversion layer 14 includes the semiconductor nanoparticle 100 described above. In addition, there is provided a semiconductor layer 13 between the lower electrode 11 and the photoelectric conversion layer 14 with an insulating layer 12 interposed in between. It is to be noted that the first surface 30A side of the semiconductor substrate 30 is an incidence surface S1 side for light and a second surface 30B side opposite to the first surface 30A is the wiring layer surface S2 side.

The photoelectric conversion section 10 is a photoelectric conversion element that absorbs light in a portion or the whole of a selective wavelength band (e.g., 700 nm or more and 2500 nm or less) to generate an electron-hole pair. In the photoelectric conversion section 10, for example, the lower electrodes 11 are provided separately from each other for the respective pixels 2A. In addition, the semiconductor layer 13, the photoelectric conversion layer 14, and the upper electrode 15 may be each provided separately for each of the pixels 2A. Alternatively, the semiconductor layer 13, the photoelectric conversion layer 14, and the upper electrode 15 may be each provided as a continuous layer extending over the plurality of pixels 2A.

The photoelectric conversion layer 14 includes the semiconductor nanoparticle 100 described above. The photoelectric conversion layer 14 may be provided, for example, by dispersing the plurality of semiconductor nanoparticles 100 in an electrically conductive polymer. The photoelectric conversion layer 14 provides a field in which electrons and holes are separated by using excitons generated in a case where light in the corresponding wavelength band is absorbed. The photoelectric conversion layer 14 may be configured to have an energy level equal to the energy level of the semiconductor layer 13 in the conduction band or shallower than the energy level of the semiconductor layer 13 in the conduction band.

The semiconductor layer 13 accumulates signal charge generated in the photoelectric conversion layer 14 and transfers the signal charge to the lower electrode 11. The semiconductor layer 13 is formed by using a material that has higher mobility of electric charge than that of the photoelectric conversion layer 14 and has a greater band gap. This makes it possible to increase the speed of transferring electric charge to the lower electrode 11 and suppress the injection of electric charge from the lower electrode 11 to the semiconductor layer 13. The semiconductor layer 13 may include, for example, an oxide semiconductor material.

The upper electrode 15 includes an electrically conductive material having light transmissivity. The upper electrodes 15 may be provided separately for the respective pixels 2A. Alternatively, the upper electrode 15 may be provided to extend over the plurality of pixels 2A. The upper electrode 15 may be formed by using an electrically conductive material such as titanium (Ti), silver (Ag), or aluminum (Al) that has a higher work function than that of the lower electrode 11. In addition, the upper electrode 15 may be formed as a multilayer film in which titanium (Ti) and aluminum (Al) are stacked.

It is to be noted that there may be provided other layers between the semiconductor layer 13 and the photoelectric conversion layer 14 and between the photoelectric conversion layer 14 and the upper electrode 15. For example, in a case where electrons are read out as signal charge, there may be additionally provided a layer including a material such as MoO₃, WO₃, or V₂O₅ having a large work function between the photoelectric conversion layer 14 and the upper electrode 15. This allows the imaging device 1 to strengthen an internal electric field generated between the lower electrode 11 and the upper electrode 15.

The lower electrode 11 includes a readout electrode 11A, an accumulation electrode 11B, and a transfer electrode 11C that are a plurality of electrodes independent from each other. The transfer electrode 11C is disposed between the readout electrode 11A and the accumulation electrode 11B. The accumulation electrode 11B and the transfer electrode 11C are covered with the insulating layer 12. Meanwhile, the readout electrode 11A is electrically coupled to the semiconductor layer 13 through an opening 12H provided in the insulating layer 12. Each of the electrodes of the lower electrode 11 may be formed by using, for example, an electrically conductive material (transparent electrically conductive material) having light transmissivity. Alternatively, each of the electrodes of the lower electrode 11 may be formed as an extremely thin film by using, for example, a metal material such as titanium (Ti), silver (Ag), aluminum (Al), magnesium (Mg), chromium (Cr), nickel (Ni), tungsten (W), or copper (Cu).

The readout electrode 11A is coupled to a floating diffusion provided on the second surface (also referred to as front surface) 30B side of the semiconductor substrate 30, for example, through an upper first contact 17A, a pad section 39A, a through electrode 34, a coupling section 41A, and a lower second contact 46. The readout electrode 11A is able to transfer signal charge generated by the photoelectric conversion layer 14 to the floating diffusion.

The accumulation electrode 11B has a voltage applied thereto, for example, through an upper second contact 17B, a pad section 39B, an unillustrated wiring line, and the like. The accumulation electrode 11B is able to accumulate signal charge generated by the photoelectric conversion layer 14 in the semiconductor layer 13. The accumulation electrode 11B may be provided to be larger than the readout electrode 11A to accumulate more electric charge.

The transfer electrode 11C is coupled to the pixel drive circuit included in the drive circuit, for example, through an upper third contact 17C and a pad section 39C. The transfer electrode 11C is provided between the readout electrode 11A and the accumulation electrode 11B. The transfer electrode 11C is able to increase the efficiency of transferring the signal charge accumulated in the accumulation electrode 11B to the readout electrode 11A.

The insulating layer 12 is provided, for example, on an interlayer insulating layer 17 to cover the lower electrode 11. The insulating layer 12 is able to electrically separate the accumulation electrode 11B and the transfer electrode 11C, and the semiconductor layer 13. In addition, the insulating layer 12 is provided with the opening 12H in association with the readout electrode 11A. The readout electrode 11A and the semiconductor layer 13 are electrically coupled through the opening 12H. The insulating layer 12 may be provided by using a silicon (Si)-based inorganic insulating material or an organic resin-based organic insulating material.

For example, a fixed electric charge layer 16A, a dielectric layer 16B, and the interlayer insulating layer 17 are provided between the first surface 30A of the semiconductor substrate 30 and the lower electrode 11.

The fixed electric charge layer 16A is a layer having positive or negative fixed electric charge. For example, the fixed electric charge layer 16A may be provided as a layer having negative fixed electric charge by using hafnium oxide, aluminum oxide, zirconium oxide, tantalum oxide, titanium oxide, or the like. In such a case, the fixed electric charge layer 16A is able to function as a hole accumulation layer. It is to be noted that the fixed electric charge layer 16A may be provided to have a stacked structure in which two or more types of layers are stacked.

The dielectric layer 16B may be provided by using, for example, an insulative material such as silicon oxide, silicon nitride, or silicon oxynitride.

The interlayer insulating layer 17 may be provided as a single layer film including, for example, one of silicon oxide, silicon nitride, silicon oxynitride, or the like or a stacked film including two or more of them.

There is provided a protective layer 18 on the upper electrode 15. The protective layer 18 may include a material having light transmissivity. The protective layer 18 may be provided as a single layer film including, for example, any one of insulative materials each having light transmissivity such as silicon oxide, silicon nitride, or silicon oxynitride or a stacked film including two or more of them.

There is provided a light shielding film 21 inside the protective layer 18 in association with the readout electrode 11A. Specifically, the light shielding film 21 may be provided to cover at least a region in which the readout electrode 11A and the photoelectric conversion layer 14 are in direct contact with each other. In addition, there is provided a color filter 22 inside the protective layer 18 in association with the accumulation electrode 11B. The color filter 22 is able to control, for example, the wavelength band of light entering the photoelectric conversion layer 14. It is to be noted that the light shielding film 21 and the color filter 22 may be provided at different positions in the film thickness direction of the protective layer 18 or may be provided at the same positions. There is further provided an optical member such as an on-chip lens 23 on the incidence surface S1 side of the protective layer 18.

The semiconductor substrate 30 includes, for example, n-type silicon (Si). The semiconductor substrate 30 includes a p-well 31 in a predetermined region. The second surface 30B of the semiconductor substrate 30 is provided, for example, with a floating diffusion (corresponding to a source/drain region 36B in the semiconductor substrate 30), an amplifier transistor AMP, a reset transistor RST, a selection transistor SEL, and a multilayer wiring line 40. It is to be noted that the multilayer wiring line 40 may include, for example, wiring layers 41, 42, and 43 that are stacked inside an insulating layer 44. In addition, the through electrode 34 is provided to penetrate the semiconductor substrate 30.

The photoelectric conversion section 10 is electrically coupled to a gate Gamp of the amplifier transistor AMP and the source/drain region 36B (i.e., floating diffusion) of the reset transistor RST through the through electrode 34. This allows the imaging device 1 to favorably transfer signal charge to the second surface 30B side of the semiconductor substrate 30. The signal charge is generated by the photoelectric conversion section 10 provided on the first surface 30A side of the semiconductor substrate 30.

One end of the through electrode 34 is electrically coupled, for example, to the coupling section 41A in the wiring layer 41. Specifically, the coupling section 41A and the gate Gamp of the amplifier transistor AMP are electrically coupled through a lower first contact 45. The coupling section 41A and the source/drain region 36B (i.e., floating diffusion) of the reset transistor RST are electrically coupled through the lower second contact 46. The other end of the through electrode 34 is electrically coupled to the readout electrode 11A, for example, through the pad section 39A and the upper first contact 17A. The through electrode 34 functions as a transmission path for signal charge generated by the photoelectric conversion section 10 by electrically coupling the photoelectric conversion section 10, and the gate Gamp of the amplifier transistor AMP and the floating diffusion.

The reset transistor RST includes a gate Grst, a channel formation region 36A, and source/drain regions 36B and 36C. The reset transistor RST is able to discharge the signal charge accumulated in the floating diffusion and reset the potential of the floating diffusion. Specifically, the gate Grst is electrically coupled to the reset line. The source/drain region 36C shares a region with a source/drain region 35B of the amplifier transistor AMP. The source/drain region 36C is coupled to the power supply line. The source/drain region 36B functions as a floating diffusion.

The amplifier transistor AMP includes the gate Gamp, a channel formation region 35A, and the source/drain regions 35B and 35C. The amplifier transistor AMP is able to modulate the electric charge amount of signal charge generated by the photoelectric conversion section 10 into a voltage. Specifically, the gate Gamp is electrically coupled to the readout electrode 11A and the source/drain region 36B (i.e., floating diffusion) of the reset transistor RST through the lower first contact 45, the coupling section 41A, the lower second contact 46, and the through electrode 34. The source/drain region 35B shares a region with the source/drain region 36C of the reset transistor RST. The source/drain region 35B is electrically coupled to the power supply line. The source/drain region 35C shares a region with a source/drain region 34B of the selection transistor SEL.

The selection transistor SEL includes a gate Gsel, a channel formation region 34A, and the source/drain regions 34B and 34C. The selection transistor SEL controls whether or not to permit a pixel signal to be outputted to the data output line. Specifically, the gate Gsel is electrically coupled to the selection line. The source/drain region 34B shares a region with the source/drain region 35C of the amplifier transistor AMP. The source/drain region 34C is electrically coupled to the data output line. The data output line outputs the pixel signal modulated by the amplifier transistor AMP into a voltage.

The imaging device 1 including the pixel 2A according to the first configuration example is able to acquire image data of light including near-infrared rays received by the photoelectric conversion section 10.

### Second Configuration Example

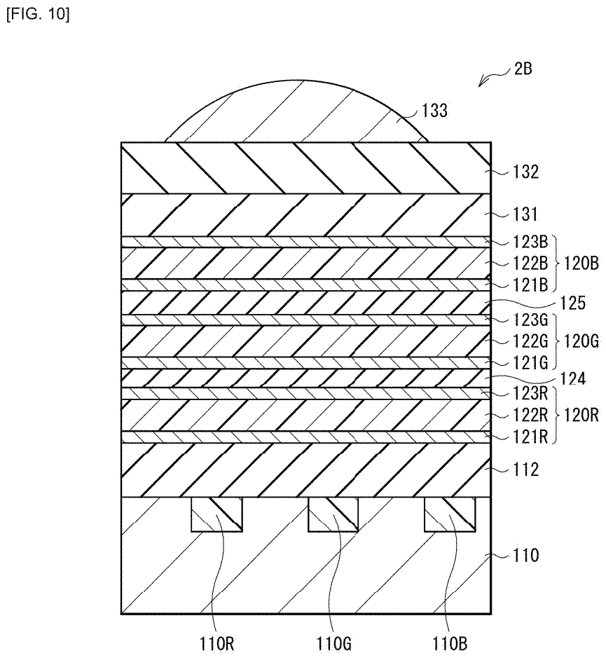

In addition, a second configuration example of the pixel 2 in the imaging device 1 according to the present embodiment is described more specifically with reference to FIG. 10. FIG. 10 is a vertical cross-sectional view of a cross-sectional configuration of a pixel 2B according to the second configuration example.

As illustrated in FIG. 10, the pixel 2B according to the second configuration example has a structure in which a red color photoelectric conversion section 120R, a green color photoelectric conversion section 120G, and a blue color photoelectric conversion section 120B are stacked in the thickness direction. The red color photoelectric conversion section 120R, the green color photoelectric conversion section 120G, and the blue color photoelectric conversion section 120B selectively photoelectrically convert pieces of light in wavelength bands different from each other.

Specifically, the pixel 2B has a stacked structure in which an insulating layer 112, the red color photoelectric conversion section 120R, an insulating layer 124, the green color photoelectric conversion section 120G, an insulating layer 125, the blue color photoelectric conversion section 120B, a protective layer 131, and a planarization layer 132 are stacked on a semiconductor substrate 110 in order. Further, there is further provided an on-chip lens 33 on a planarization layer 32 in the pixel 2B.

The pixel 2B according to the second configuration example is provided with the red color photoelectric conversion section 120R, the green color photoelectric conversion section 120G, and the blue color photoelectric conversion section 120B that are stacked in the incidence direction of light. This makes it possible to acquire a plurality of color signals by using the pixel 2B alone without using any color filter or the like. Such a type of pixel 2B is also referred to as vertical spectroscopic pixel. At least one or more of the red color photoelectric conversion section 120R, the green color photoelectric conversion section 120G, or the blue color photoelectric conversion section 120B may include the semiconductor nanoparticles 100 corresponding to the wavelengths of pieces of light to be photoelectrically converted.

The semiconductor substrate 110 is, for example, a p-type silicon (Si) substrate. There are provided a red color electricity storage layer 110R, a green color electricity storage layer 110G, and a blue color electricity storage layer 110B as n-type regions in predetermined regions of a semiconductor substrate 120. The red color electricity storage layer 110R, the green color electricity storage layer 110G, and the blue color electricity storage layer 110B respectively accumulate signal charge resulting from photoelectric conversion by the red color photoelectric conversion section 120R, the green color photoelectric conversion section 120G, and the blue color photoelectric conversion section 120B. The red color electricity storage layer 110R, the green color electricity storage layer 110G, and the blue color electricity storage layer 110B may be each formed, for example, by doping the semiconductor substrate 110 with an n-type impurity such as phosphorus (P) or arsenic (As).

The surface of the semiconductor substrate 110 opposite to the surface provided with the insulating layer 112 is provided with a circuit formation layer (not illustrated) in which respective pixel transistor groups corresponding to the red color photoelectric conversion section 120R, the green color photoelectric conversion section 120G, and the blue color photoelectric conversion section 120B and a peripheral circuit portion such as a logic circuit are formed.

Each of the pixel transistor groups may include, for example, MOS transistors including a transfer transistor, a reset transistor, an amplifier transistor, a selection transistor, and the like. The respective pixel transistor groups are provided for the red color photoelectric conversion section 120R, the green color photoelectric conversion section 120G, and the blue color photoelectric conversion section 120B. The respective pixel transistor groups convert, into pixel signals, signal charge resulting from photoelectric conversion by the red color photoelectric conversion section 120R, the green color photoelectric conversion section 120G, and the blue color photoelectric conversion section 120B.

The insulating layer 112 includes, for example, silicon oxide, silicon nitride, silicon oxynitride, hafnium oxide, or the like. The insulating layer 112 may be provided to have a single layer structure or a multilayer structure of a material or materials described above. The insulating layer 112 is provided with a plug or an electrode (not illustrated) that electrically couples the red color electricity storage layer 110R and the red color photoelectric conversion section 120R. Similarly, the insulating layer 112 is provided with a plug or an electrode (not illustrated) that electrically couples the green color electricity storage layer 110G and the green color photoelectric conversion section 120G and a plug or an electrode (not illustrated) that electrically couples the blue color electricity storage layer 110B and the blue color photoelectric conversion section 120B.

The red color photoelectric conversion section 120R is configured by stacking a first electrode 121R, a semiconductor film 122R, and a second electrode 123R on the insulating layer 112 in order. The red color photoelectric conversion section 120R generates an electron-hole pair by selectively absorbing red light (e.g., light in a wavelength band of 600 nm to 750 nm).

The green color photoelectric conversion section 120G is configured by stacking a first electrode 121G, a semiconductor film 122G, and a second electrode 123G on the insulating layer 124 in order. The green color photoelectric conversion section 120G generates an electron-hole pair by selectively absorbing green light (e.g., light in a wavelength band of 500 nm to 650 nm).

The blue color photoelectric conversion section 120B is configured by stacking a first electrode 121B, a semiconductor film 122B, and a second electrode 123B on the insulating layer 125 in order. The blue color photoelectric conversion section 120B generates an electron-hole pair by selectively absorbing blue light (e.g., light in a wavelength band of 400 nm to 550 nm).

Each of the semiconductor films 122R, 122G, and 122B is a photoelectric conversion layer that generates an electron-hole pair by absorbing light in a selective wavelength band (i.e., red light, green light, or blue light).

The first electrodes 121R, 121G, and 121B are provided for each of the pixels. The first electrodes 121R, 121G, and 121B are electrically coupled to unillustrated plugs provided inside the semiconductor substrate 110. Each of the first electrodes 121R, 121G, and 121B may include, for example, a transparent electrically conductive material having light transmissivity such as ITO (Indium-Tin-Oxide).

Each of the second electrodes 123R, 123G, and 123B is electrically coupled through an unillustrated contact section to the power supply of the circuit formation layer, the ground, or the like provided on the surface of the semiconductor substrate 110 opposite to the surface provided with the insulating layer 112. As with the first electrodes 121R, 121G, and 121B, the second electrodes 123R, 123G, and 123B may include transparent electrically conductive materials.

It is to be noted that there may be provided hole transport layers between the semiconductor film 122R and the second electrode 123R, between the semiconductor film 122G and the second electrode 123G, and between the semiconductor film 122B and the second electrode 123B. It is possible to configure each of the hole transport layers by using, for example, molybdenum oxide, nickel oxide, or the like. In a case where holes are extracted from the semiconductor films 122R, 122G, and 122B as signal charge, the hole transport layers are able to facilitate the holes generated by the semiconductor films 122R, 122G, and 122B to move the second electrodes 123R, 123G, and 123B. Each of the hole transport layers may have a stacked structure of molybdenum oxide and nickel oxide.

Each of the insulating layers 124 and 125 includes, for example, silicon oxide, silicon nitride, silicon oxynitride, hafnium oxide, or the like. Each of the insulating layers 124 and 125 may be provided to have a single layer structure or a multilayer structure of a material or materials described above.

The protective layer 131 is provided by using a material having light transmissivity. For example, the protective layer 131 may be provided by using a single layer film or a stacked film of silicon oxide, silicon nitride, silicon oxynitride, or the like. The protective layer 131 is able to protect the red color photoelectric conversion section 120R, the green color photoelectric conversion section 120G, and the blue color photoelectric conversion section 120B from external moisture or the like.

The planarization layer 132 may be provided by using an acrylic-based resin material, a styrene-based resin material, or an epoxy-based resin material. It is to be noted that the planarization layer 132 is provided as necessary.

An on-chip lens 133 allows incident light to concentrate on the light receiving surface of each of the red color photoelectric conversion section 120R, the green color photoelectric conversion section 120G, and the blue color photoelectric conversion section 120B.

The imaging device 1 including the pixel 2B according to the second configuration example is able to acquire, by one pixel, a plurality of signals in a wider wavelength range including near-infrared rays.

### (Application to Electronic Apparatus)

The technology according to the present disclosure may be applied to a general electronic apparatus including a solid-state imaging device such as a camera module including an optical lens system or the like in addition to the solid-state imaging device, an imaging apparatus such as a digital still camera or a video camera, a portable terminal apparatus (e.g., a smartphone or a tablet terminal) having an imaging function, or a copier in which the solid-state imaging device is used as an image reader.

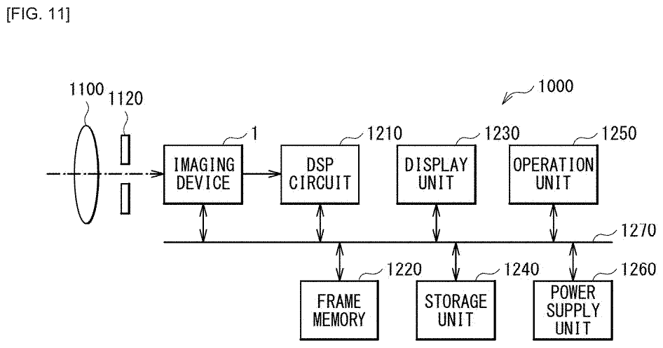

FIG. 11 is a block diagram illustrating a configuration example of an electronic apparatus 1000 including the imaging device 1 according to any of the embodiment and the modification example described above.

As described above, the electronic apparatus 1000 is, for example, an electronic apparatus such as an imaging apparatus such as a digital still camera or a video camera or a portable terminal apparatus such as a smartphone or a tablet terminal.

As illustrated in FIG. 11, the electronic apparatus 1000 includes, for example, a lens 1100, a shutter 1120, the imaging device 1 according to the embodiment described above, a DSP (Digital Signal Processor) circuit 1210, a frame memory 1220, a display unit 1230, a storage unit 1240, an operation unit 1250, and a power supply unit 1260. The DSP circuit 1210, the frame memory 1220, the display unit 1230, the storage unit 1240, the operation unit 1250, and the power supply unit 1260 are coupled to each other through a bus line 1270.

The imaging device 1 outputs image data corresponding to light coming through the lens 1100 and the shutter 1120. The DSP circuit 1210 is a circuit that performs signal processing on the image data outputted from the imaging device 1. The frame memory 1220 is a storage device that temporarily holds the image data subjected to the signal processing by the DSP circuit 1210 in units of frames. The display unit 1230 includes, for example, a liquid crystal display device or an OLED (Organic Light Emitting Diode) display device. The display unit 1230 displays a moving image or a still image captured by the imaging device 1 on the basis of the image data. The storage unit 1240 is a storage device such as a semiconductor memory or a hard disk drive that stores the image data of the moving image or the still image captured by the imaging device 1. The operation unit 1250 is an input device that outputs operation instructions for various functions of the electronic apparatus 1000 on the basis of an operation by a user. The power supply unit 1260 is an operation power supply for the DSP circuit 1210, the frame memory 1220, the display unit 1230, the storage unit 1240, and the operation unit 1250 to appropriately supply power to each of the units.

### (Application to Mobile Body)

For example, the technology according to the present disclosure may be applied to a device to be mounted on a mobile body of any type such as an automobile, an electric vehicle, a hybrid electric vehicle, a motorcycle, a bicycle, a personal mobility, an airplane, a drone, a vessel, or a robot.

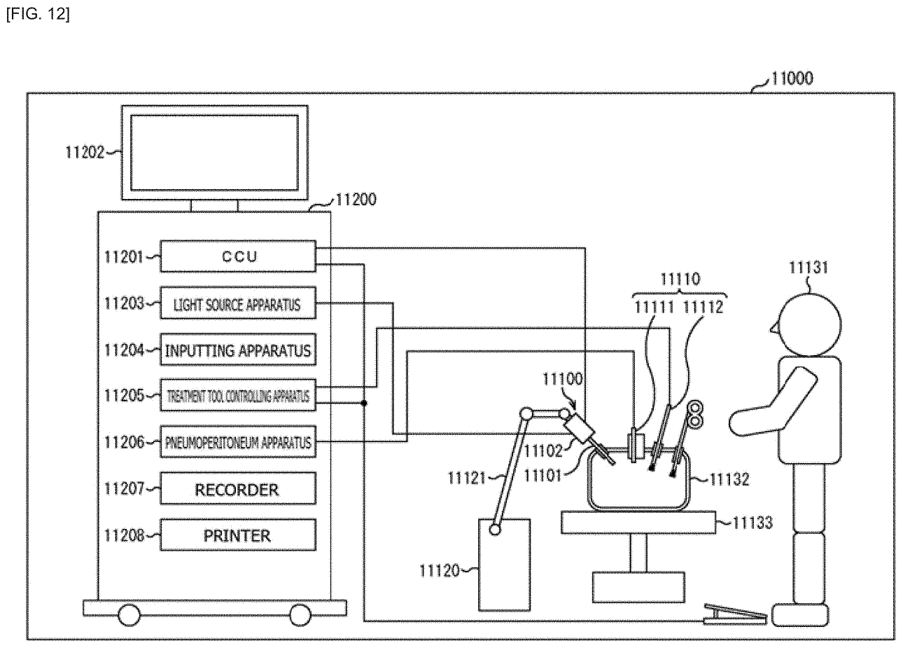

FIG. 12 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 12, an audio speaker 12061, a display section 12062, and an instrument panel 12063 are illustrated as the output device. The display section 12062 may, for example, include at least one of an on-board display and a head-up display.

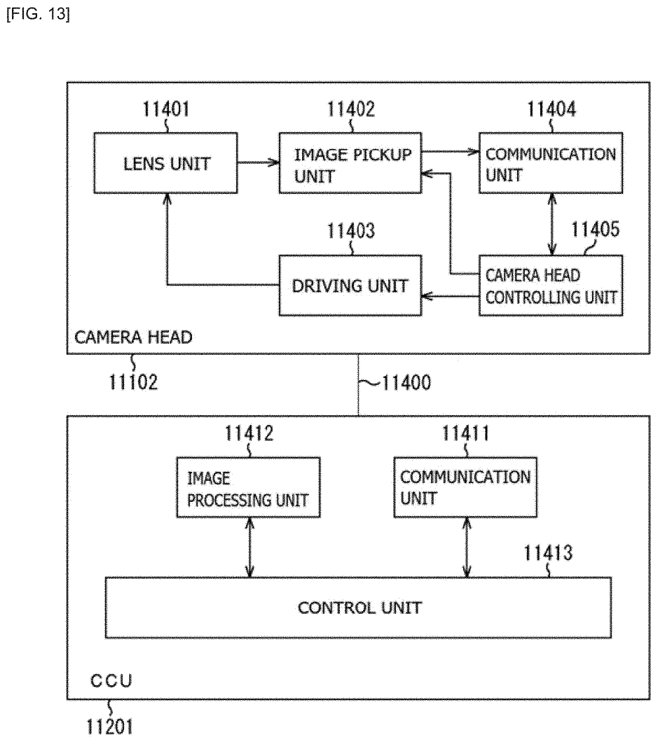

FIG. 13 is a diagram depicting an example of the installation position of the imaging section 12031.

In FIG. 13, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 13 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure may be applied has been described above. The technology according to the present disclosure may be applied to the imaging section 12031 or the like among the components described above. The application of the technology according to the present disclosure to the imaging section 12031 makes it possible to increase the response characteristics in photoelectric conversion. It is therefore possible to obtain a captured image having higher image quality. This allows the microcomputer 12051 to perform automatic driving or the like with higher accuracy.

### (Application to Endoscopic Surgery System)

For example, the technology according to the present disclosure may be applied to an endoscopic surgery system.

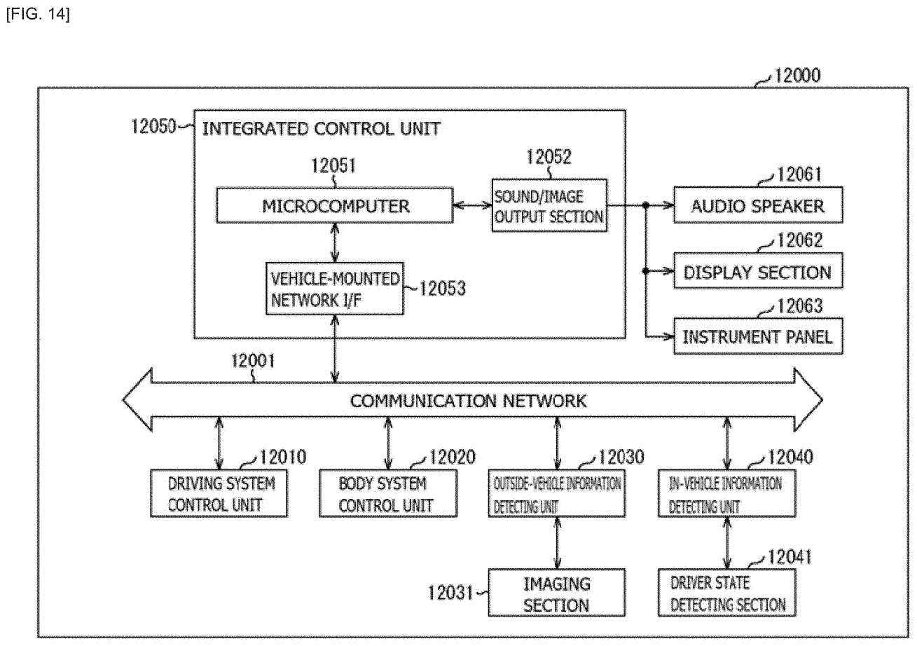

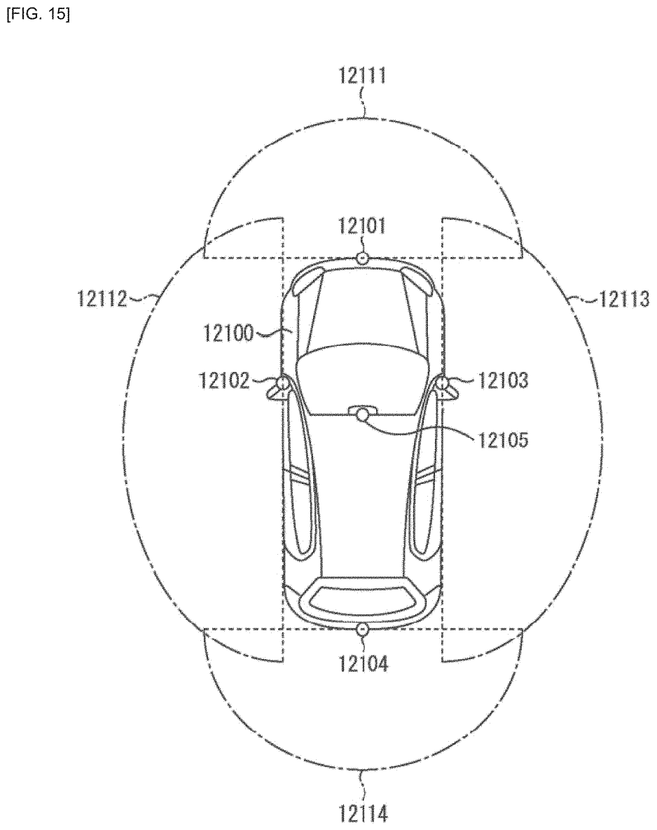

FIG. 14 is a view depicting an example of a schematic configuration of an endoscopic surgery system to which the technology according to an embodiment of the present disclosure (present technology) can be applied.

In FIG. 14, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 15 is a block diagram depicting an example of a functional configuration of the camera head 11102 and the CCU 11201 depicted in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure may be applied has been described above. The technology according to the present disclosure may be applied, for example, to the endoscope 11100 or the image pickup unit 11402 of the camera head 11102 among the components described above. The application of the technology according to the present disclosure to the image pickup unit 11402 makes it possible to increase, for example, the response characteristics in photoelectric conversion. It is thus possible to obtain a captured image having higher image quality. The endoscopic surgery system thus allows a surgeon to treat a surgical region as if the surgeon directly observed the surgical region.

It is to be noted that the endoscopic surgery system has been described here as an example, but the technology according to the present disclosure may be additionally applied, for example, to a microscopic surgery system or the like.

The technology according to the present disclosure has been described above with reference to the embodiment. However, the technology according to the present disclosure is not limited to the embodiment or the like described above. A variety of modifications are possible.

Further, not all of the components and operations described in each of the embodiments are necessary as the components and operations according to the present disclosure. For example, among the components according to each of the embodiments, a component that is not described in an independent claim reciting the most generic concept of the present disclosure should be understood as an optional component.

The terms used throughout this specification and the appended claims should be construed as “non-limiting” terms. For example, the term “including” or “included” should be construed as “not limited to what is described as being included”. The term “having” should be construed as “not limited to what is described as having”.

The terms used in this specification are used merely for the convenience of description and include terms that are not used to limit the configuration and the operation. For example, the terms such as “right”, “left”, “up”, and “down” only indicate directions in the diagrams being referred to. In addition, the terms “inside” and “outside” only indicate a direction toward the center of a component of interest and a direction away from the center of a component of interest, respectively. The same applies to terms similar to these and terms with the similar purpose.

It is to be noted that the technology according to the present disclosure may have configurations as follows. The technology according to the present disclosure having the following configurations decreases the inter-particle distance between semiconductor nanoparticles each including a particle body including a semiconductor core and a monoatomic ligand bonded to the surface of the particle body to make it possible to further increase the mobility of electric charge between the semiconductor nanoparticles. This allows an imaging device including a photoelectric conversion layer including the semiconductor nanoparticles to exhibit higher response characteristics in photoelectric conversion. It is thus possible to acquire a captured image having higher image quality. Effects attained by the technology according to the present disclosure are not necessarily limited to the effects described herein, but may include any of the effects described in the present disclosure.

(1)

An imaging device including

a photoelectric conversion layer including a semiconductor nanoparticle including a particle body and a monoatomic ligand, the particle body including a semiconductor core, the monoatomic ligand being bonded to a surface of the particle body.

(2)

The imaging device according to (1), in which the semiconductor core includes each of a Group I element and a Group VI element.

(3)

The imaging device according to (2), in which the semiconductor core includes at least one or more of AgInSe₂, AgInTe₂, Ag₂Se, or Ag₂Te.

(4)

The imaging device according to any one of (1) to (3), in which the monoatomic ligand includes any of a chlorine atom, a bromine atom, an iodine atom, or a sulfur atom.

(5)

The imaging device according to (4), in which the monoatomic ligand includes a sulfur atom.

(6)

The imaging device according to any one of (1) to (5), in which

the particle body further includes a shell that is provided to cover the semiconductor core, and

the shell includes at least one or more of PbO, PbO₂, Pb₃O₄, ZnS, ZnSe, ZnTe, GaS, or GaSe.

(7)

The imaging device according to any one of (1) to (6), in which the photoelectric conversion layer further includes a metal ion interposed between the semiconductor nanoparticles.

(8)

A semiconductor film including

a semiconductor nanoparticle including a particle body and a monoatomic ligand, the particle body including a semiconductor core including at least two or more elements selected from a Group I element, a Group III element, a Group V element, and a Group VI element, the monoatomic ligand being bonded to a surface of the particle body.

(9)

A dispersion liquid including

a semiconductor nanoparticle including a particle body and a monoatomic ligand, the particle body including a semiconductor core including at least two or more elements selected from a Group I element, a Group III element, a Group V element, and a Group VI element, the monoatomic ligand being bonded to a surface of the particle body.

This application claims the priority on the basis of Japanese Patent Application No. 2020-123305 filed with Japan Patent Office on Jul. 17, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising
a photoelectric conversion layer including a semiconductor nanoparticle including a particle body and a monoatomic ligand, the particle body including a semiconductor core, the monoatomic ligand being bonded to a surface of the particle body.

2. The imaging device according to claim 1, wherein the semiconductor core includes each of a Group I element and a Group VI element.

3. The imaging device according to claim 2, wherein the semiconductor core includes at least one or more of AgInSe₂, AgInTe₂, Ag₂Se, or Ag₂Te.

4. The imaging device according to claim 1, wherein the monoatomic ligand includes any of a chlorine atom, a bromine atom, an iodine atom, or a sulfur atom.

5. The imaging device according to claim 4, wherein the monoatomic ligand includes a sulfur atom.

6. The imaging device according to claim 1, wherein
the particle body further includes a shell that is provided to cover the semiconductor core, and
the shell includes at least one or more of PbO, PbO₂, Pb₃O₄, ZnS, ZnSe, ZnTe, GaS, or GaSe.

7. The imaging device according to claim 1, wherein the photoelectric conversion layer further includes a metal ion interposed between the semiconductor nanoparticles.

8. A semiconductor film comprising
a semiconductor nanoparticle including a particle body and a monoatomic ligand, the particle body including a semiconductor core including at least two or more elements selected from a Group I element, a Group III element, a Group V element, and a Group VI element, the monoatomic ligand being bonded to a surface of the particle body.

9. A dispersion liquid comprising
a semiconductor nanoparticle including a particle body and a monoatomic ligand, the particle body including a semiconductor core including at least two or more elements selected from a Group I element, a Group III element, a Group V element, and a Group VI element, the monoatomic ligand being bonded to a surface of the particle body.
